(19) United States
(12) Patent Application Publication
(10) Pub. No.: US 2026/0298725 A1
(43) Pub. Date: Oct. 1, 2026

(54) ELECTRONIC DEVICE

(71) Applicant: KABUSHIKI KAISHA TOYOTA JIDOSHOKKI, Aichi-ken (JP)

(72) Inventors: Hiroki ISHIHARA, Kariya-shi (JP); Kuniyoshi FUJIHASHI, Kariya-shi (JP); Takeshi OKOCHI, Kariya-shi (JP)

(73) Assignee: KABUSHIKI KAISHA TOYOTA JIDOSHOKKI, Aichi-ken (JP)

(21) Appl. No.: 19/573,642

(22) Filed: Mar. 20, 2026

(30) Foreign Application Priority Data
Mar. 27, 2025 (JP) 2025-053732

(51) Int. Cl. G01K 1/20; G01K 1/16; H05K 1/02; H05K 1/181

(52) U.S. Cl. CPC G01K 1/20; G01K 1/16; H05K 1/0298; H05K 1/181; H05K 2201/10053; H05K 2201/10151

(57) ABSTRACT

An electronic device includes a substrate, a conductive pattern provided in the substrate, a heat-generating element having a lead that is electrically connected to the conductive pattern, a temperature sensor configured to detect a temperature of the heat-generating element, an electronic component other than the heat-generating element, the electronic component being mounted over the conductive pattern, and a temperature-detection conductive pattern provided in the substrate and electrically connected to the lead. The lead is disposed between the conductive pattern and the temperature-detection conductive pattern. The temperature sensor is configured to detect a temperature of the temperature-detection conductive pattern.

### CROSS-REFERENCE TO RELATED APPLICATIONS

This application is based upon and claims the benefit of priority from Japanese Patent Application No. 2025-053732, filed on Mar. 27, 2025, the entire contents of which are incorporated herein by reference.

### BACKGROUND

### 1. Field

The present disclosure relates to an electronic device.

### 2. Description of Related Art

Electronic devices include a substrate, a conductive pattern disposed on the substrate, and a heat-generating element. The conductive pattern is provided on the substrate. The heat-generating element includes a lead. The lead is electrically connected to the conductive pattern. JP2023-154870 discloses an example of an electronic device that includes a temperature sensor. The temperature sensor detects a temperature of the heat-generating element. Specifically, the temperature sensor detects the temperature of the heat-generating element by sensing the temperature of heat conducted from the lead to a portion of the conductive pattern located in the vicinity of the lead.

In such electronic devices, an electronic component other than the heat-generating element may be mounted on the conductive pattern to which the lead is connected. In this case, heat generated by that electronic component may be conducted to the portion of the conductive pattern located in the vicinity of the lead. As a result, the temperature detected by the temperature sensor may substantially deviate from the actual temperature of the heat-generating element. Consequently, there is a risk that the temperature sensor cannot accurately detect the temperature of the heat-generating element.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An electronic device according to an aspect includes a substrate, a conductive pattern provided in the substrate, a heat-generating element having a lead that is electrically connected to the conductive pattern, a temperature sensor configured to detect a temperature of the heat-generating element, an electronic component other than the heat-generating element, the electronic component being mounted over the conductive pattern, and a temperature-detection conductive pattern provided in the substrate and electrically connected to the lead. The lead is disposed between the conductive pattern and the temperature-detection conductive pattern. The temperature sensor is configured to detect a temperature of the temperature-detection conductive pattern.

Other features and aspects will be apparent from the following detailed description, the drawings, and the claims.

### BRIEF DESCRIPTION OF THE DRAWINGS

FIG. 1 is a cross-sectional view of an electronic device according to an embodiment.

FIG. 2 is a cross-sectional view taken along line 2-2 in FIG. 1.

FIG. 3 is a cross-sectional view taken along line 3-3 in FIG. 1.

FIG. 4 is an enlarged cross-sectional view illustrating a portion of the electronic device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

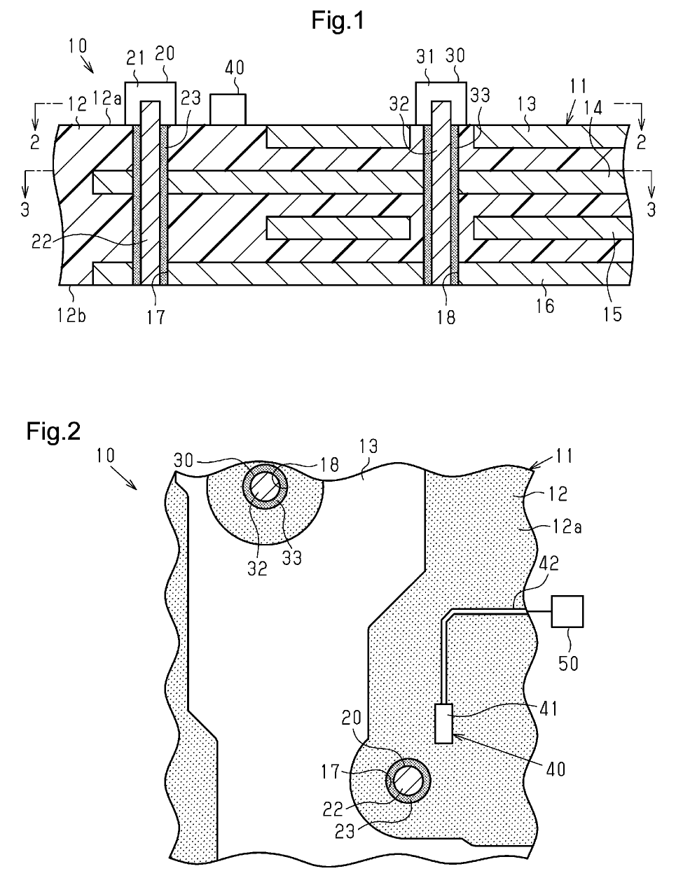

An electronic device according to an embodiment will now be described with reference to FIGS. 1-4.

### Basic Configuration of Electronic Device

As shown in FIG. 1, an electronic device 10 includes a substrate 11. The substrate 11 includes an insulating layer 12, a first conductive pattern 13, a second conductive pattern 14, a third conductive pattern 15, and a fourth conductive pattern 16. The electronic device 10 includes a heat-generating element 20 and an electronic component 30.

The insulating layer 12 is plate-shaped. The insulating layer 12 is made of resin. The insulating layer 12 includes a front surface 12a and a rear surface 12b. The front surface 12a is one of two opposing surfaces of the insulating layer 12 in the thickness direction of the insulating layer 12. The rear surface 12b is the other one of the two opposing surfaces of the insulating layer 12 in the thickness direction of the insulating layer 12.

The first conductive pattern 13 is provided on the front surface 12a of the insulating layer 12. The second conductive pattern 14 is provided inside the insulating layer 12. The third conductive pattern 15 is provided inside the insulating layer 12 at a position closer to the rear surface 12b of the insulating layer 12 than the second conductive pattern 14 is. The fourth conductive pattern 16 is provided on the rear surface 12b of the insulating layer 12. The first conductive pattern 13, the second conductive pattern 14, the third conductive pattern 15, and the fourth conductive pattern 16 are insulated by a portion of the insulating layer 12 in the thickness direction of the insulating layer 12. The first conductive pattern 13, the second conductive pattern 14, the third conductive pattern 15, and the fourth conductive pattern 16 are formed of copper foil.

The substrate 11 has a first through-hole 17. The first through-hole 17 extends through the substrate 11 in the thickness direction of the substrate 11. The first through-hole 17 extends through the insulating layer 12, the second conductive pattern 14, and the fourth conductive pattern 16.

The substrate 11 has a second through-hole 18. The second through-hole 18 extends through the substrate 11 in the thickness direction of the substrate 11. The second through-hole 18 extends through the insulating layer 12, the second conductive pattern 14, and the fourth conductive pattern 16.

The heat-generating element 20 includes a body 21 and a lead 22. The heat-generating element 20 is a switching element. The body 21 is placed on the front surface 12a of the insulating layer 12. The lead 22 extends through the first through-hole 17. Thus, the lead 22 extends from the body 21 through the substrate 11 in the thickness direction of the substrate 11. The lead 22 extends through the insulating layer 12, the second conductive pattern 14, and the fourth conductive pattern 16.

Solder 23 is provided between the first through-hole 17 and the lead 22. Accordingly, the lead 22 is soldered to the substrate 11. The lead 22 is electrically connected to the second conductive pattern 14 and the fourth conductive pattern 16 via the solder 23. In this manner, the second conductive pattern 14 and the fourth conductive pattern 16 are conductive patterns which are provided in the substrate 11 and to which the lead 22 is electrically connected. The lead 22 does not extend through either the first conductive pattern 13 or the third conductive pattern 15. The lead 22 is not electrically connected to either the first conductive pattern 13 or the third conductive pattern 15. The lead 22 is insulated from the first conductive pattern 13 and the third conductive pattern 15 by a portion of the insulating layer 12.

The electronic component 30 includes a component body 31 and a component lead 32. The electronic component 30 is, for example, a coil or a capacitor. The component body 31 is placed on the front surface 12a of the insulating layer 12. The component lead 32 extends through the second through-hole 18. Accordingly, the component lead 32 extends from the component body 31 through the substrate 11 in the thickness direction of the substrate 11. The component lead 32 extends through the insulating layer 12, the second conductive pattern 14, and the fourth conductive pattern 16.

Solder 33 is provided between the second through-hole 18 and the component lead 32. Accordingly, the component lead 32 is soldered to the substrate 11. The component lead 32 is electrically connected to the second conductive pattern 14 and the fourth conductive pattern 16 via the solder 33. The component lead 32 does not extend through either the first conductive pattern 13 or the third conductive pattern 15. The component lead 32 is not electrically connected to either the first conductive pattern 13 or the third conductive pattern 15. The component lead 32 is insulated from the first conductive pattern 13 and the third conductive pattern 15 by a portion of the insulating layer 12.

In this manner, the electronic component 30 other than the heat-generating element 20 is mounted over the first conductive pattern 13 and the third conductive pattern 15. The first conductive pattern 13 and the third conductive pattern 15 are conductive patterns over which the electronic component 30 other than the heat-generating element 20 is mounted.

As shown in FIG. 2, the electronic device 10 includes a temperature sensor 40 that detects the temperature of the heat-generating element 20. Further, the electronic device 10 includes a controller 50. The temperature sensor 40 includes a sensor portion 41 and a wiring portion 42. The sensor portion 41 is placed on the front surface 12a of the insulating layer 12. The wiring portion 42 is electrically connected to the controller 50.

Information regarding the temperature detected by the temperature sensor 40 is sent to the controller 50 via the wiring portion 42. The controller 50 stores, in advance, a program that controls driving of the heat-generating element 20 based on the temperature detected by the temperature sensor 40. The controller 50 stores, in advance, a program that stops driving of the heat-generating element 20 when the temperature detected by the temperature sensor 40 reaches a preset temperature.

The controller 50 is a microcomputer mounted on the substrate 11. The controller 50 may include, for example, at least one dedicated hardware circuit and/or at least one processor (control circuit) that operates in accordance with a computer program (software). The processor includes a CPU and a memory (e.g., RAM and ROM). The memory stores program codes or commands configured to cause the processor to execute various processes. The memory, or a computer-readable medium, includes any type of medium that is accessible by general-purpose computers and dedicated computers.

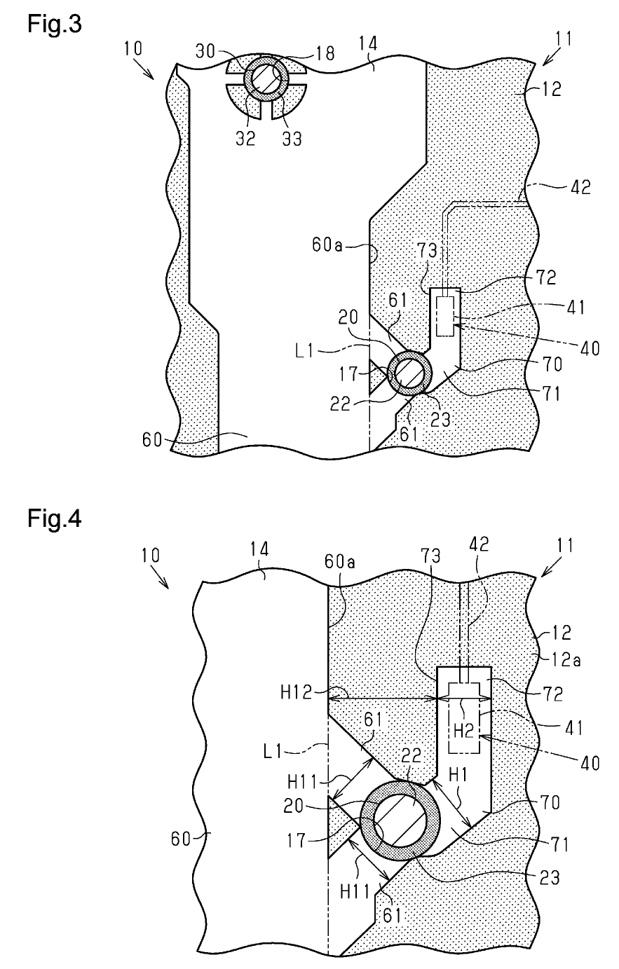

FIG. 3 illustrates the second conductive pattern 14. Since the fourth conductive pattern 16 has the same configuration as the second conductive pattern 14, the fourth conductive pattern 16 will not be described. As shown in FIG. 3, the second conductive pattern 14 includes a body pattern 60 and multiple connection patterns 61. The second conductive pattern 14 includes two connection patterns 61.

The body pattern 60 includes an extension edge 60a that extends linearly. The two connection patterns 61 protrude from an imaginary straight line L1 obtained by extending the extension edge 60a. The two connection patterns 61 extend toward each other as the distance from the imaginary straight line L1 increases. The two connection patterns 61 extend linearly toward each other from the body pattern 60. The end of each connection pattern 61 opposite to the body pattern 60 is connected to the lead 22 via the solder 23. Accordingly, each of the two connection patterns 61 connects the body pattern 60 to the lead 22. Each of the two connection patterns 61 extends linearly from the body pattern 60 toward the lead 22. In other words, each of the two connection patterns 61 extends in an elongated shape from the body pattern 60 toward the lead 22. The lead 22 is connected to each connection pattern 61 via the solder 23. Thus, the lead 22 is electrically connected to the second conductive pattern 14.

### Temperature-Detection Conductive Pattern

As shown in FIG. 4, the electronic device 10 includes a temperature-detection conductive pattern 70. The temperature-detection conductive pattern 70 includes a first extension 71 and a second extension 72. The first extension 71 extends from the lead 22 via the solder 23, in a direction opposite to the connection pattern 61 and toward the extension edge 60a of the body pattern 60. The second extension 72 extends linearly along the extension edge 60a from the end of the first extension 71 on the side opposite to the lead 22. Thus, the temperature-detection conductive pattern 70 extends in an elongated shape from the lead 22 via the solder 23. The width of the temperature-detection conductive pattern 70 is constant.

The lead 22 is disposed between the two connection patterns 61 and the first extension 71. Accordingly, the lead 22 is disposed between the second conductive pattern 14 and the temperature-detection conductive pattern 70.

The sensor portion 41 of the temperature sensor 40 is disposed at a position overlapping the second extension 72 of the temperature-detection conductive pattern 70 in the thickness direction of the substrate 11. In this manner, the temperature sensor 40 is disposed at a position overlapping the temperature-detection conductive pattern 70 in the thickness direction of the substrate 11. The sensor portion 41 is configured to detect the temperature of the second extension 72 of the temperature-detection conductive pattern 70. Accordingly, the temperature sensor 40 detects the temperature of the temperature-detection conductive pattern 70.

The width H1 of the first extension 71 is smaller than the sum of the widths H11 of the two connection patterns 61. Accordingly, the width of the temperature-detection conductive pattern 70 is smaller than the width H11 of each of the two connection patterns 61. The widths H11 of the connection patterns 61 are the widths of the ends of the connection patterns 61 located closer to the lead 22.

### Slit

A slit 73 is provided between the second conductive pattern 14 and the temperature-detection conductive pattern 70. The slit 73 is provided between the extension edge 60a of the body pattern 60 and the second extension 72 of the temperature-detection conductive pattern 70. The width H12 of the slit 73 is larger than the width H2 of the second extension 72. Accordingly, the width H12 of the slit 73 is larger than the width of the temperature-detection conductive pattern 70. The width H12 of the slit 73 is the shortest distance between the extension edge 60a and the second extension 72.

### Operation of the Embodiment

The operation of the embodiment will now be described.

As shown in FIG. 3, the electronic component 30 is mounted over the second conductive pattern 14, to which the component lead 32 is connected. Since the temperature-detection conductive pattern 70 extends from the lead 22, only heat from the lead 22 is readily conducted to the temperature-detection conductive pattern 70, while the heat generated from the electronic component 30 is not readily conducted to the temperature-detection conductive pattern 70. The temperature sensor 40 detects the temperature of the second extension 72 of the temperature-detection conductive pattern 70. Thus, the temperature detected by the temperature sensor 40 is prevented from significantly deviating from the actual temperature of the heat-generating element 20.

The temperature detected by the temperature sensor 40 is conducted to the controller 50 via the wiring portion 42. The controller 50 determines whether the temperature detected by the temperature sensor 40 has reached a preset temperature. When the temperature detected by the temperature sensor 40 has reached a preset temperature, the controller 50 stops driving the heat-generating element 20.

### Advantages of the Embodiment

The embodiment has the following advantages.
(1) The temperature-detection conductive pattern 70 extends from the lead 22. Further, the lead 22 is disposed between the second conductive pattern 14 and the temperature-detection conductive pattern 70. Accordingly, only heat from the lead 22 is readily conducted to the temperature-detection conductive pattern 70, while heat conduction from the electronic component 30 to the temperature-detection conductive pattern 70 is limited. The temperature sensor 40 detects the temperature of the temperature-detection conductive pattern 70. Thus, the temperature detected by the temperature sensor 40 is prevented from significantly deviating from the actual temperature of the heat-generating element 20. This allows the temperature sensor 40 to detect the temperature of the heat-generating element 20 accurately.
(2) The temperature-detection conductive pattern 70 extends in an elongated shape from the lead 22. Accordingly, only heat from the lead 22 is more readily conducted to the temperature-detection conductive pattern 70, while heat from the electronic component 30 to the temperature-detection conductive pattern 70 is less readily conducted. This allows the temperature sensor 40 to detect the temperature of the heat-generating element 20 more accurately.
(3) The slit 73 is provided between the second conductive pattern 14 and the temperature-detection conductive pattern 70. Accordingly, the slit 73 readily limits situations in which heat from the electronic component 30 is conducted from the second conductive pattern 14 to the temperature-detection conductive pattern 70. This allows the temperature sensor 40 to detect the temperature of the heat-generating element 20 more accurately.
(4) The width H12 of the slit 73 is larger than the width H2 of the second extension 72 of the temperature-detection conductive pattern 70. For example, there may be a case in which the width H12 of the slit 73 is less than or equal to the width H2 of the second extension 72 of the temperature-detection conductive pattern 70. Compared to this case, the slit 73 more readily limits situations in which the heat generated from the electronic component 30 is conducted from the second conductive pattern 14 to the temperature-detection conductive pattern 70. This allows the temperature sensor 40 to detect the temperature of the heat-generating element 20 more accurately.
(5) The temperature sensor 40 is disposed at a position overlapping the temperature-detection conductive pattern 70 in the thickness direction of the substrate 11. Accordingly, the temperature sensor 40 readily detects the temperature of the temperature-detection conductive pattern 70. This allows the temperature sensor 40 to detect the temperature of the heat-generating element 20 more accurately.
(6) The width H1 of the first extension 71 of the temperature-detection conductive pattern 70 is smaller than the sum of the widths H11 of the two connection patterns 61. Accordingly, compared to when, for example, the width H1 of the first extension 71 of the temperature-detection conductive pattern 70 is greater than or equal to the sum of the widths H11 of the two connection patterns 61, heat from the lead 22 is readily conducted to the temperature-detection conductive pattern 70. Thus, the temperature detected by the temperature sensor 40 readily tracks the actual temperature of the heat-generating element 20. This allows the temperature sensor 40 to detect the temperature of the heat-generating element 20 more accurately.
(7) The heat-generating element 20 is a switching element. Accordingly, reliability of the switching element is ensured. In particular, since the switching element is susceptible to thermal effects, controlling driving of the switching element based on the temperature detected by the temperature sensor 40 improves durability of the switching element.

### Modifications

The above embodiment may be modified as follows. The above embodiment and the following modifications can be combined as long as the combined modifications remain technically consistent with each other.

In the embodiment, the temperature-detection conductive pattern 70 does not have to extend in an elongated shape from the lead 22. Accordingly, the shape of the temperature-detection conductive pattern 70 is not particularly limited. The temperature-detection conductive pattern 70 only needs to extend from the lead 22.

In the embodiment, the width H12 of the slit 73 may be equal to the width H2 of the second extension 72 of the temperature-detection conductive pattern 70.

In the embodiment, the width H12 of the slit 73 may be smaller than the width H2 of the second extension 72 of the temperature-detection conductive pattern 70.

In the embodiment, the slit 73 does not have to be provided between the second conductive pattern 14 and the temperature-detection conductive pattern 70. In this case, for example, the temperature-detection conductive pattern 70 does not have to include the second extension 72. Accordingly, the temperature-detection conductive pattern 70 may only include the first extension 71.

In the embodiment, the temperature sensor 40 does not have to be disposed at a position overlapping the temperature-detection conductive pattern 70 in the thickness direction of the substrate 11. The temperature sensor 40 does not have to overlap the temperature-detection conductive pattern 70 in the thickness direction of the substrate 11.

In the embodiment, the width H1 of the first extension 71 of the temperature-detection conductive pattern 70 may be equal to the sum of the widths H11 of the two connection patterns 61.

In the embodiment, the width H1 of the first extension 71 of the temperature-detection conductive pattern 70 may be larger than the sum of the widths H11 of the two connection patterns 61.

In the embodiment, the second conductive pattern 14 may include three or more connection patterns 61. As long as multiple connection patterns 61 are provided, the number of the connection patterns 61 is not particularly limited.

In the embodiment, the second conductive pattern 14 does not have to include the connection pattern 61. In this case, the lead 22 is connected to the body pattern 60 via the solder 23.

In the embodiment, the heat-generating element 20 is not limited to a switching element. The type of the heat-generating element 20 is not particularly limited, as long as it generates heat.

In the embodiment, the substrate 11 does not have to include either the third conductive pattern 15 or the fourth conductive pattern 16.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An electronic device, comprising:
a substrate;
a conductive pattern provided in the substrate;
a heat-generating element having a lead that is electrically connected to the conductive pattern;
a temperature sensor configured to detect a temperature of the heat-generating element;
an electronic component other than the heat-generating element, the electronic component being mounted over the conductive pattern; and
a temperature-detection conductive pattern provided in the substrate and electrically connected to the lead, wherein
the lead is disposed between the conductive pattern and the temperature-detection conductive pattern, and
the temperature sensor is configured to detect a temperature of the temperature-detection conductive pattern.

2. The electronic device according to claim 1, wherein
the temperature-detection conductive pattern extends in an elongated shape from the lead.

3. The electronic device according to claim 2, wherein
a slit is provided between the conductive pattern and the temperature-detection conductive pattern.

4. The electronic device according to claim 3, wherein
the slit has a larger width than the temperature-detection conductive pattern.

5. The electronic device according to claim 1, wherein
the temperature sensor is disposed at a position overlapping the temperature-detection conductive pattern in a thickness direction of the substrate.

6. The electronic device according to claim 2, wherein
the conductive pattern includes a main pattern and multiple connection patterns that connect the main pattern to the lead,
each of the connection patterns extends in an elongated shape from the body pattern toward the lead, and
a width of the temperature-detection conductive pattern is smaller than a sum of widths of the connection patterns.

7. The electronic device according to claim 1, wherein
the heat-generating element is a switching element.
